(19) United States
(12) Patent Application Publication
(10) Pub. No.: US 2024/0361400 A1
(43) Pub. Date: Oct. 31, 2024

(54) POWER RECEIVING DEVICE AND WIRELESS POWER TRANSMISSION SYSTEM

(71) Applicant: CANON KABUSHIKI KAISHA, Tokyo (JP)

(72) Inventor: JUN MORITA, Tokyo (JP)

(21) Appl. No.: 18/643,868

(22) Filed: Apr. 23, 2024

(30) Foreign Application Priority Data
Apr. 25, 2023 (JP) 2023-071899

(51) Int. Cl. G01R 31/40; G01R 19/165; H02J 50/12

(52) U.S. Cl. CPC G01R 31/40; G01R 19/16571; H02J 50/12

(57) ABSTRACT

A power receiving device that wirelessly receives power from a power transmission device includes a power receiving antenna, a plurality of power receiving circuits that each includes a switching element and is connected in parallel with each other, a plurality of current detection sensors that is arranged in the plurality of power receiving circuits and is configured to output detection values, one or more processors, and one or more memories that store a computer-readable instruction for causing, when executed by the one or more processors, the power receiving device to compare the detection values output from the plurality of current detection sensors, and determine whether an abnormality has occurred based on results of comparison.

### BACKGROUND

### Field

The present disclosure relates to a power receiving device that wirelessly receives power from a power transmission device and a wireless power transmission system.

### Description of the Related Art

In recent years, there have been studied and developed wireless power transmission systems that wirelessly supply power of several kW or more to apparatuses such as electric vehicles (EVs). In a wireless power transmission system handling power of several kW or more, a large current flows to switching elements in a power transmission circuit and a power receiving circuit. For example, WO2016-038737A1 discusses a system in which a plurality of power transmission circuits is connected in parallel in order to distribute the current that flows to the switching elements. In addition, in a wireless power transmission system, in the event of an abnormal state, it is necessary to detect that abnormality immediately. For example, Japanese Patent Application Laid-Open No. 2016-220532 discusses a configuration of detecting the value of the current flowing to the power receiving circuit exceeding a threshold and determining whether the event is an abnormality.

### SUMMARY

According to an various embodiments of the present disclosure, a power receiving device that wirelessly receives power from a power transmission device includes a power receiving antenna, a plurality of power receiving circuits that each includes a switching element and is connected in parallel with each other, a plurality of current detection units that is arranged in the plurality of power receiving circuits and is configured to output detection values, one or more processors, and one or more memories that store a computer-readable instruction for causing, when executed by the one or more processors, the power receiving device to compare the detection values output from the plurality of current detection sensors, and determine whether an abnormality has occurred based on results of comparison.

Further features of the present disclosure will become apparent from the following description of exemplary embodiments with reference to the attached drawings.

### BRIEF DESCRIPTION OF THE DRAWINGS

FIG. 1 is a schematic diagram illustrating a wireless power transmission system according to a first exemplary embodiment.

FIG. 2 is a configuration diagram illustrating a power receiving circuit according to the first exemplary embodiment.

FIG. 3 is a configuration diagram illustrating a determination unit according to the first exemplary embodiment.

FIGS. 4A to 4C are current waveform diagrams according to the first exemplary embodiment.

FIG. 5 is an abnormality detection flowchart according to the first exemplary embodiment.

FIG. 6 is a schematic diagram illustrating a wireless power transmission system according to a second exemplary embodiment.

FIGS. 7A to 7C are current waveform diagrams according to the second exemplary embodiment.

FIG. 8 is a schematic diagram illustrating a wireless power transmission system according to a third exemplary embodiment.

FIG. 9 is a configuration diagram illustrating a determination unit according to the third exemplary embodiment.

FIG. 10 is a table showing simulation results according to the third exemplary embodiment.

FIG. 11 is an abnormality detection flowchart according to the third exemplary embodiment.

### DESCRIPTION OF THE EMBODIMENTS

Hereinafter, exemplary embodiments of the present disclosure will be described with reference to the drawings.

A wireless power transmission system according to one embodiment of the present disclosure will be described taking a method called electromagnetic induction/magnetic resonance that transmits power using a magnetic field or using both an electric field and a magnetic field. However, other processes for transmitting power can also be used. For example, an electric field coupling method that transmits power using mainly an electric field is also applicable.

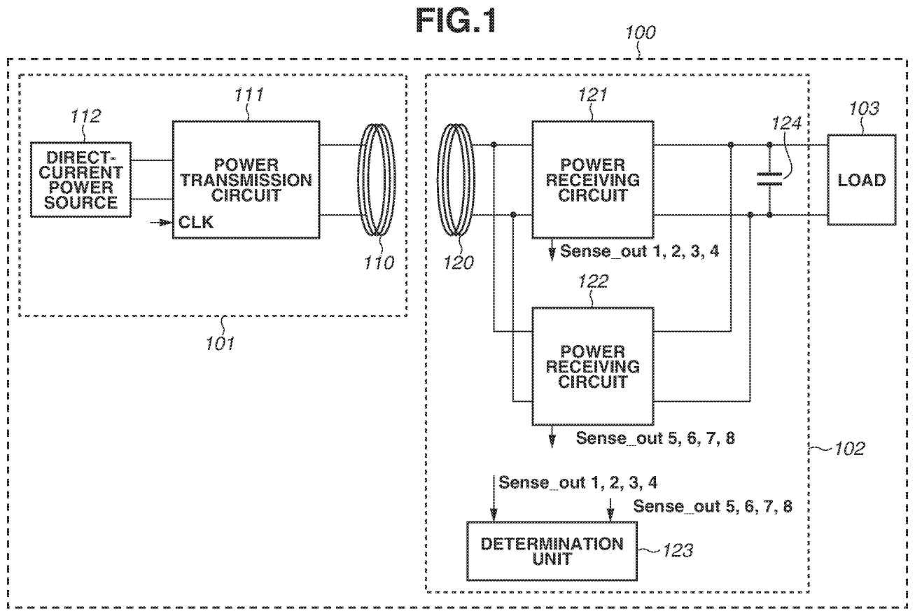

FIG. 1 is a configuration diagram illustrating a wireless power transmission system according to a first exemplary embodiment. A wireless power transmission system 100 includes a power transmission unit 101 including a power transmission antenna 110, a power transmission circuit 111, and a direct-current power source 112, a power receiving unit 102 including a power receiving antenna 120, power receiving circuits 121 and 122, a determination unit 123, and a smoothing capacitor 124, and a load 103.

The power transmission circuit 111 is configured by a publicly known switching circuit that is used if the electromagnetic induction method or the magnetic resonance method is adopted. The power transmission circuit 111 converts a direct-current voltage supplied from the direct-current power source 112 into an alternating-current voltage at a frequency of a clock (hereinafter, CLK) signal generated by a clock generation circuit (not illustrated), and outputs the alternating-current voltage to the power transmission antenna 110. The power receiving antenna 120 is coupled to the power transmission antenna 110 to receive the alternating-current voltage. The power receiving circuits 121 and 122 are also configured by publicly known rectifier circuits that are used if the electromagnetic induction method or the magnetic resonance method is adopted, and the power receiving circuits 121 and 122 convert the received alternating-current voltage into a direct-current voltage and supply the direct-current voltage to the load 103.

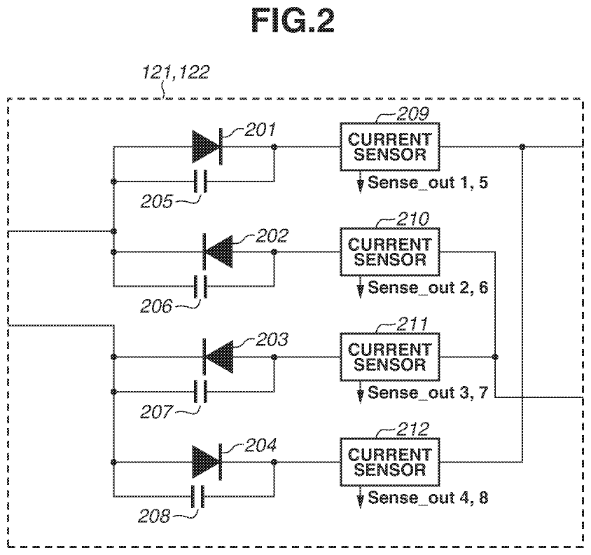

Subsequently, a configuration of the power receiving circuits 121 and 122 will be described taking as an example a full-wave rectifier circuit in which diodes are used as switching elements. A synchronous rectifier using a metal-oxide semiconductor field-effect transistor (MOSFET) or a gallium nitride field-effect transistor (GAN-FET) is also applicable, for example. FIG. 2 illustrates a configuration of the power receiving circuits 121 and 122 according to the present exemplary embodiment. The power receiving circuits 121 and 122 each include switching elements 201, 202, 203, and 204, and capacitors 205, 206, 207, and 208, and current sensors 209, 210, 211, and 212.

The current sensors are connected in series with the switching elements and are configured to detect the currents flowing in the switching elements and output voltage values proportional to the currents. Specifically, in the power receiving circuit 121, the current sensor 209 outputs Sense_out1, the current sensor 210 outputs Sense_out2, the current sensor 211 outputs Sense_out3, and the current sensor 212 outputs Sense_out4.

In the power receiving circuit 122, the current sensor 209 outputs Sense_out5, the current sensor 210 outputs Sense_out6, the current sensor 211 outputs Sense_out7, and the current sensor 212 outputs Sense_out8. The current sensors here output the voltage values as detected values, but may output values proportional to the current values or may output values indicating the current values as detected values. The plurality of current sensors is implemented at substantially identical positions in the power receiving circuits with which they are connected in parallel, and if possible, the power receiving circuits are also desirably identical in wiring pattern. The capacitors connected in parallel with the switching elements are intended to adjust the ON times of the switching elements, and a constant is determined in accordance with the value of rated load. The capacitors need not be connected if the parasitic capacities of the switching elements are sufficiently large or if there is no need to adjust the ON times of the switching elements.

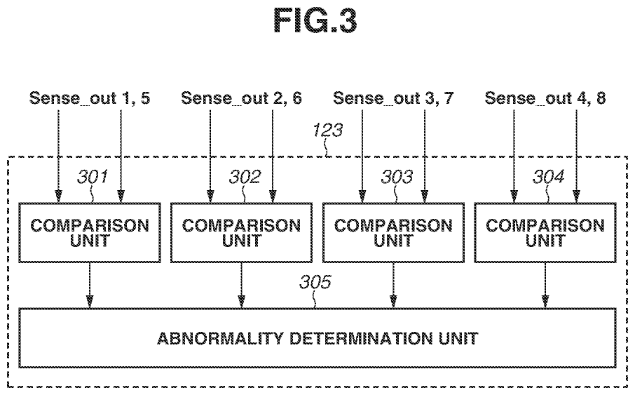

FIG. 3 illustrates a configuration of the determination unit 123 according to the present exemplary embodiment. The determination unit 123 includes comparison units 301, 302, 303, and 304, and an abnormality determination unit 305. The comparison unit 301 compares the values of Sense_out1 and Sense_out5, the comparison unit 302 compares the values of Sense_out2 and Sense_out6, the comparison unit 303 compares the values of Sense_out3 and Sense_out7, and the comparison unit 304 compares the values of Sense_out4 and Sense_out8. Based on the results of the comparisons, the abnormality determination unit 305 determines whether any abnormality has occurred. If any abnormality has occurred, the abnormality determination unit 305 outputs an alert signal (not illustrated). The signals input to the comparison units may have instantaneous values of Sense_out1 to Sense_out8 or may have time averaged values of Sense_out1 to Sense_out8. Hereinafter, a case where the time averaged values are acquired will be described. However, the abnormality detection can also be performed in a similar manner in a case where the instantaneous values are acquired.

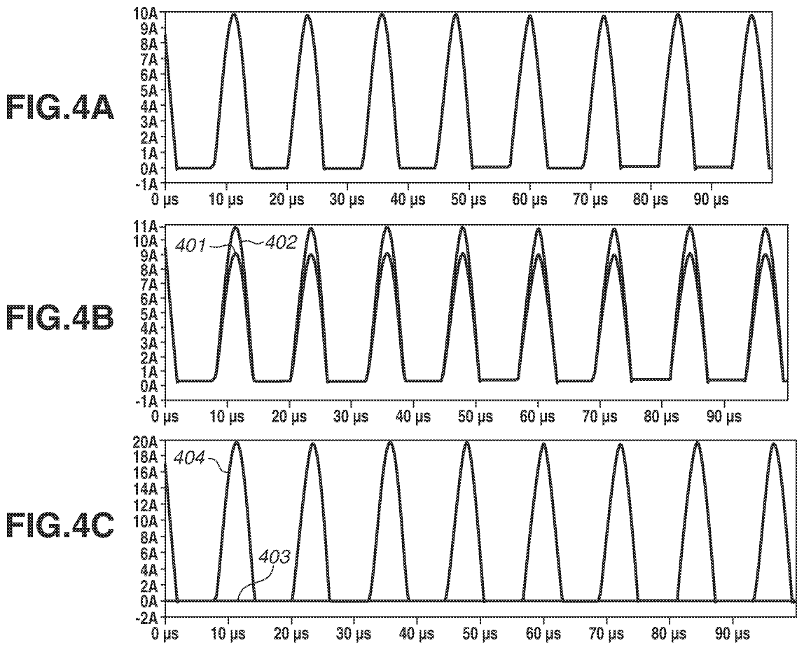

FIGS. 4A to 4C illustrate the results of waveform simulations of currents flowing in the current sensors 209 in each of the power receiving circuits 121 and 122 in the configurations illustrated in FIGS. 1 and 2. In the simulations of FIGS. 4A to 4C, it is assumed that the switching elements 202, 203, and 204 of the power receiving circuit 121 and the switching elements 201, 202, 203, and 204 of the power receiving circuit 122 are all normally operating. The simulations have been performed with a change only in the operation of the switching element 201 in the power receiving circuit 121. The normal operation of the switching element means that the forward voltage or the ON resistance has a standard value. In addition, the simulations have been performed by a simple method for changing the ON resistance of a diode.

FIG. 4A illustrates the results of the simulation of current waveforms where the switching element 201 of the power receiving circuit 121 is normally operating. As illustrated in FIG. 4A, it can be seen that the currents flow in a period during which the switching elements are ON, and that the waveforms of the currents flowing in the switching elements 201 in the power receiving circuit 121 and the power receiving circuit 122 overlap each other and are completely identical.

When a comparison of current values is made between the current flowing in the current sensor 209 of the power receiving circuit 121 and the current flowing in the current sensor 209 of the power receiving circuit 122, the difference is zero. When the average values of the currents during the period in which the currents flow in the current sensors 209 of the power receiving circuits 121 and 122 are compared, the division value is one.

FIG. 4B illustrates the results of the simulation of a case where the switching element 201 of the power receiving circuit 121 is larger in ON resistance than the switching element 201 of the power receiving circuit 122 within a range of manufacturing errors. The waveform of the current flowing in the current sensor 209 of the power receiving circuit 121 is indicated as a waveform 401, and the waveform of the current flowing in the current sensor 209 of the power receiving circuit 122 is indicated as a waveform 402.

When a comparison of current values is made between the current sensor 209 of the power receiving circuit 121 and the current sensor 209 of the power receiving circuit 122, the current flowing in the switching element with a larger ON resistance is smaller. In the period during which the switching element is ON and the current flows, the average of the current values in the waveform 401 is 5.41 A, and the average of the current values in the waveform 402 is 4.71 A. When the average values are compared, the division value is about 0.87 (=4.71/5.41).

FIG. 4C illustrates the results of the simulation of a case where the switching element 201 of the power receiving circuit 121 is in an open state due to occurrence of an abnormality. The waveform of the current flowing in the current sensor 209 of the power receiving circuit 121 is indicated as a waveform 403, and the waveform of the current flowing in the current sensor 209 of the power receiving circuit 122 is indicated as a waveform 404. It can be seen that the current waveform 403 always shows substantially 0 A. When a comparison of current values is made between the current sensor 209 of the power receiving circuit 121 and the current sensor 209 of the power receiving circuit 122, the difference is as very large as about 20 A at the maximum. When the average values of the currents during the period in which the currents flow in the current sensor 209 of the power receiving circuit 121 and the current sensor 209 of the power receiving circuit 122 are compared, the division value is as very small as 1/1000 or less.

Thus, as seen from the simulation results in FIGS. 4A to 4C, it is possible to detect an abnormality in each power receiving circuit by making a comparison between the values of the currents flowing in the current sensors. In addition, in the present exemplary embodiment, the results of simulations of a case where a load resistance is 10Ω are presented. The absolute values of the currents flowing in the current sensor 209 of the power receiving circuit 121 and the current sensor 209 of the power receiving circuit 122 are inversely proportional to the magnitude of the load resistance. However, the ratio between the values of the currents flowing in the current sensor 209 of the power receiving circuit 121 and the current sensor 209 of the power receiving circuit 122 remains almost unchanged even with a change in the load. For example, in FIG. 4B, the ratio between the average currents under a load of 10Ω is 0.87, and the ratio between the average currents under a load of 20Ω is 0.88, which shows almost no difference. Therefore, if a predetermined value is set as threshold and the ratio between the current values in the current sensors falls below the threshold, it is possible to determine that an abnormality has occurred regardless of the magnitude of the load.

In the present exemplary embodiment, the description has been given of a case where the number of power receiving circuits is two. Alternatively, the number of power receiving circuits may be three or more. In that case, the maximum value and minimum value of the current values of each current sensor are selected, and a division value is calculated using the minimum value as a numerator and the maximum value as a denominator. If the division value is equal to or greater than a threshold, it is determined that the state is normal, and if division value is less than the threshold, it is determined that the state is abnormal.

Even if the ON resistances of the switching elements are different in the range of normal manufacturing errors, the minimum value/the maximum value of the current values of each current sensor tends to be smaller with an increase in the number of power receiving circuits.

For example, if five power receiving circuits are connected in parallel in the configuration of FIG. 1, the minimum value/the maximum value of the current values of each current sensor is about 0.6. If the number of power receiving circuits is ten, the minimum value/the maximum value of the current values of each current sensor is about 0.58. In consideration of a system in practical use, the appropriate or reasonable number of power receiving circuits is about ten at the maximum. In addition, in consideration of the fact that some types of switching elements may have large manufacturing errors, an appropriate or reasonable threshold is 0.5.

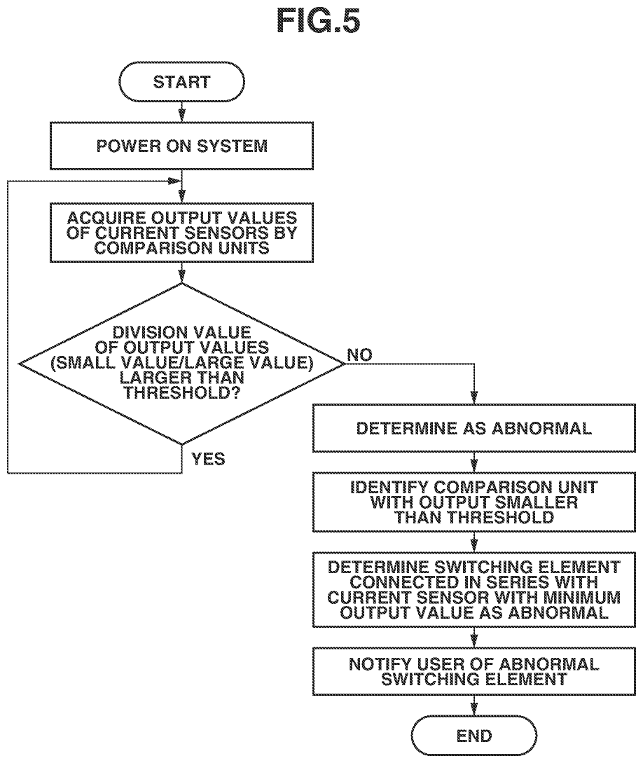

FIG. 5 is a flowchart illustrating a flow of operations of the wireless power transmission system including activation, detection of an abnormality, and notification to a user. First, the user or an external device powers on the wireless power transmission system, and the comparison units acquire output values proportional to the currents flowing in the current sensors implemented in the power receiving circuits. The comparison units each calculate the minimum value/the maximum value of the output values of the current sensors and transmit the minimum value/the maximum value to the abnormality detection unit. If all the output values of the comparison units are equal to or greater than the threshold, the abnormality detection unit determines that the state is normal, and if any of the output values is less than the threshold, the abnormality detection unit determines that the state is abnormal. The abnormality detection unit identifies the comparison unit of which the output is less than the threshold, and determines that the switching element connected in series with the current sensor with a minimum output value, among the current sensors connected to the identified comparison unit, is abnormal.

Finally, the user will be notified of the abnormal switching element.

In the first exemplary embodiment, the description has been given of the system in which the current sensors are arranged in series with all the switching elements. In a second exemplary embodiment, a configuration in which current sensors are connected between power receiving circuits and a load will be described. This configuration makes it possible to decrease the number of current sensors as compared to that in the first exemplary embodiment.

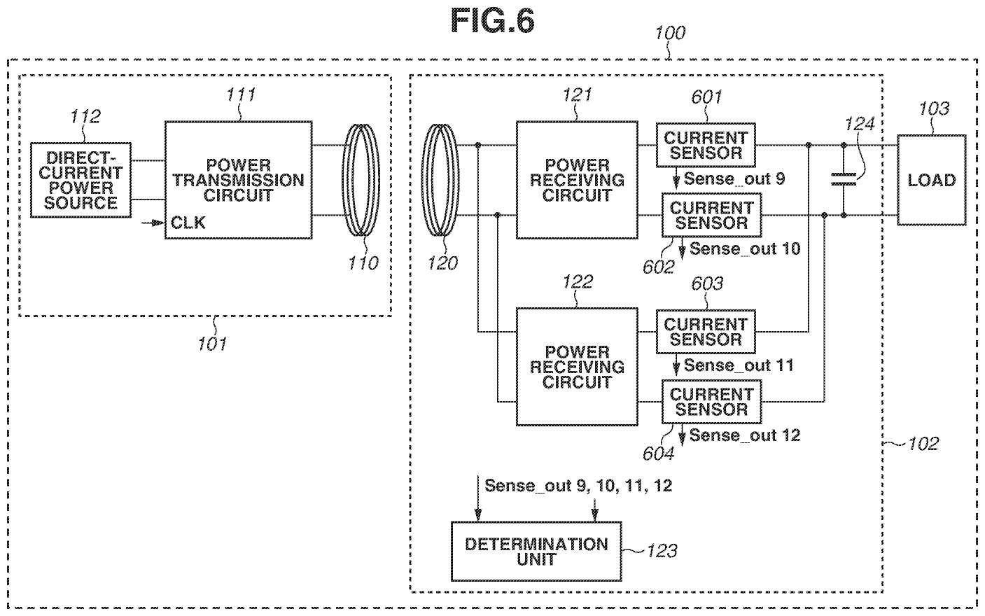

FIG. 6 is a configuration diagram of a wireless power transmission system according to the present exemplary embodiment. The components similar to those illustrated in FIG. 1 are given the same reference signs and numerals as those in FIG. 1, and current sensors 601, 602, 603, and 604 are connected to output units of power receiving circuits 121 or 122 and a ground GND.

Also in the present exemplary embodiment, a plurality of current sensors is implemented at substantially identical positions in the power receiving circuits with which they are connected in parallel. If possible, the wiring patterns are desirably identical between the power receiving circuits. The current sensor 601 outputs Sense_out9, the current sensor 602 outputs Sense_out10, the current sensor 603 outputs Sense_out11, and the current sensor 604 outputs Sense_out12. Specific configurations of the power receiving circuits 121 and 122 according to the second exemplary embodiment are different from the configurations of the power receiving circuits 121 and 122 according to the first exemplary embodiment illustrated in FIG. 2 in the current sensors 209, 210, 211, and 212 removed. A configuration of a determination unit 123 according to the second exemplary embodiment is different from the configuration of the determination unit 123 according to the first exemplary embodiment illustrated in FIG. 3 in the comparison units 303 and 304 removed.

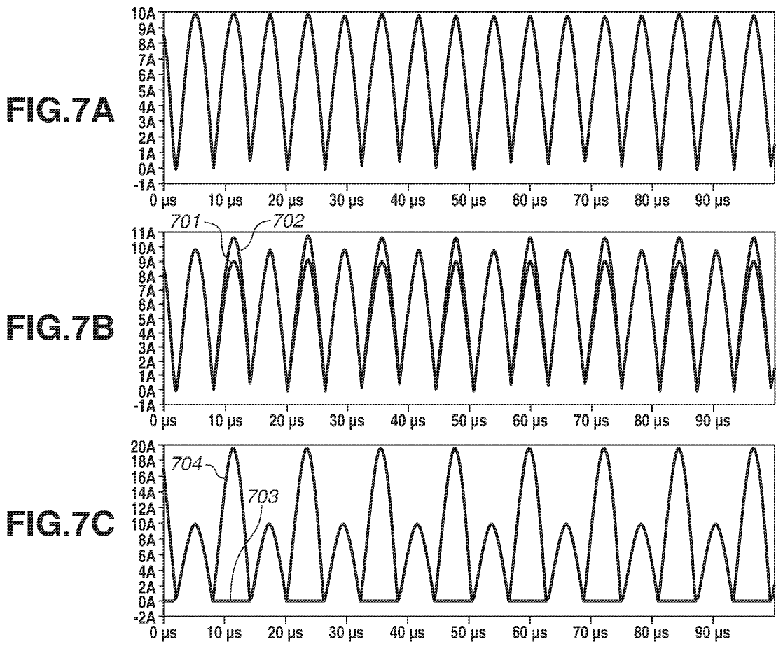

FIGS. 7A to 7C illustrates the results of simulations of waveforms of currents flowing in the current sensors 601 and 603 in the configuration of FIG. 6. As in the simulations of the first exemplary embodiment, it is assumed that the switching elements 202, 203, and 204 in the power receiving circuit 121 and the switching elements 201, 202, 203, and 204 in the power receiving circuit 122 are all normally operating. In the simulations, only the operation of the switching element 201 in the power receiving circuit 121 is changed.

FIG. 7A illustrates the state in which the switching element 201 in the power receiving circuit 121 is normally operating. The waveforms of the currents flowing in the current sensors 601 and 603 overlap and are completely identical. Unlike the simulation results of FIGS. 4A to 4C, the current flows into the current sensor 601 in both the period during which the switching element 201 is ON and the period during which the switching element 204 is ON. FIG. 7B illustrates the state in which the ON resistance of the switching element 201 in the power receiving circuit 121 is large in a range of manufacturing errors. The waveform of the current flowing in the current sensor 601 is indicated as a waveform 701, and the waveform of the current flowing in the current sensor 603 is indicated as a waveform 702. The waveforms of the currents flowing in the current sensors 601 and 603 are different only in the period during which the switching element 201 is ON, and the waveforms of the currents flowing in the current sensors 601 and 603 overlap and are completely identical in the period during which the switching element 204 is ON as in FIG. 7A. Further, FIG. 7C illustrates the state in which an abnormality has occurred in the switching element 201 in the power receiving circuit 121 and the ON resistance of the switching element 201 is abnormally large. The waveform of the current flowing in the current sensor 601 is indicated as a waveform 703, and the waveform of the current flowing in the current sensor 603 is indicated as a waveform 704.

The current waveform 703 shows substantially zero only in the period during which the switching element 201 is ON, which is different from the normal state. As in the case of FIG. 7B, the waveforms 703 and 704 overlap and are completely identical in the period during which the switching element 204 is ON.

As seen from the simulation results in FIGS. 7A to 7C, the switching element in the ON state is different depending on the period. Thus, in order to detect an abnormality in each switching element, it is necessary to detect which switching element is ON in which period. For example, the detection can be performed by arranging a high resistor in parallel with the switching element and transmitting the values of voltages generated on both ends of the high resistor to a micro-controller unit (MCU). Therefore, also in the configuration according to the present exemplary embodiment, it is possible to minimize the number of current sensors and detect an abnormality in each switching element by comparing the minimum value and maximum value of the current values acquired by the current sensors.

In a third exemplary embodiment, a configuration that makes it possible to detect a plurality of abnormal power receiving circuits will be described. As in the first and second exemplary embodiments, the configuration according to the third exemplary embodiment is also applicable to the case where two power receiving circuits are provided and an abnormality occurs in one of them.

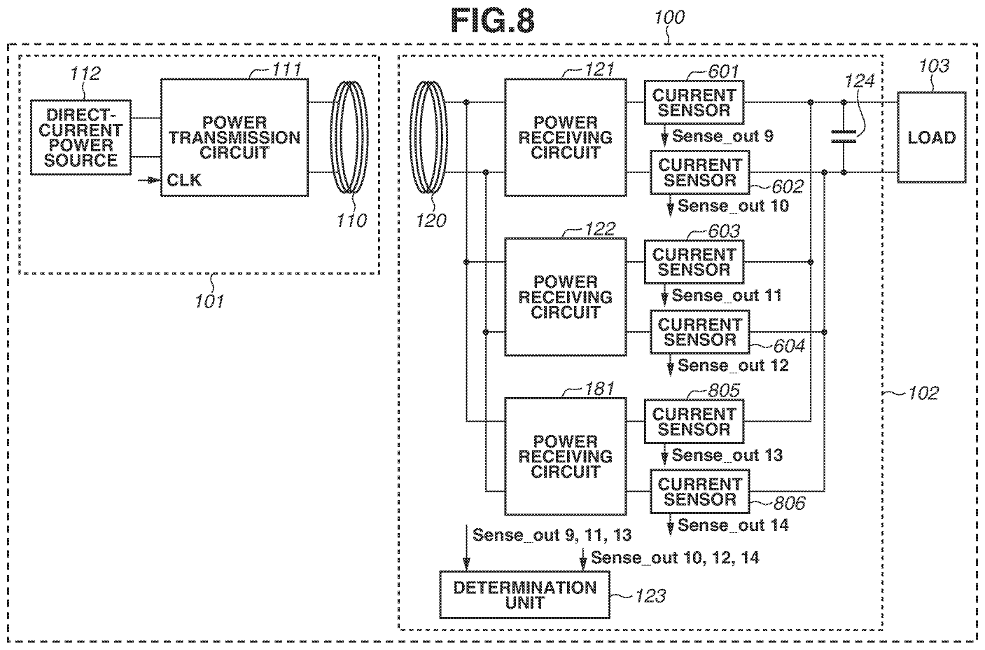

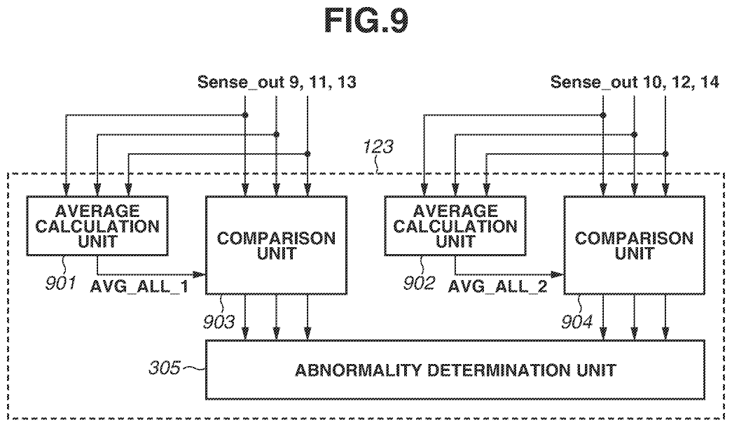

FIG. 8 illustrates a case where three power receiving circuits are provided in the configuration of FIG. 6. In FIG. 8, the components similar to those illustrated in FIG. 6 are given the same reference signs and numerals as those in FIG. 6, and a power receiving circuit 181 and current sensors 805 and 806 are added to the configuration in FIG. 6. The current sensor 805 outputs Sense_out13, and the current sensor 806 outputs Sense_out14. FIG. 9 illustrates a configuration of a determination unit 123 according to the present exemplary embodiment. The determination unit 123 includes average calculation units 901 and 902, comparison units 903 and 904, and an abnormality determination unit 305. The components similar to those in the first exemplary embodiment illustrated in FIG. 3 are given the same reference signs and numerals as those in FIG. 3.

The average calculation unit 901 calculates and outputs an average value AVG_ALL1 of Sense_out9, Sense_out11 and Sense_out13, and the average calculation unit 902 calculates and outputs an average value AVG_ALL2 of Sense_out10, Sense_out12, and Sense_out14. The comparison unit 903 compares Sense_out9, Sense_out11, and Sense_out13 with AVG_ALL1, the comparison unit 904 compares Sense_out10, Sense_out12, and Sense_out14 with AVG_ALL2, and the abnormality determination unit 305 determines whether an abnormality has occurred based on the results of the comparisons. If an abnormality has occurred, the abnormality determination unit 305 outputs an alert signal (not illustrated). The output signals from the current sensors to the comparison units and the average calculation units may have instantaneous values or time averaged values. Hereinafter, a case where the time averaged values are acquired will be described. However, the abnormality detection can also be performed in a similar manner in a case where the instantaneous values are acquired.

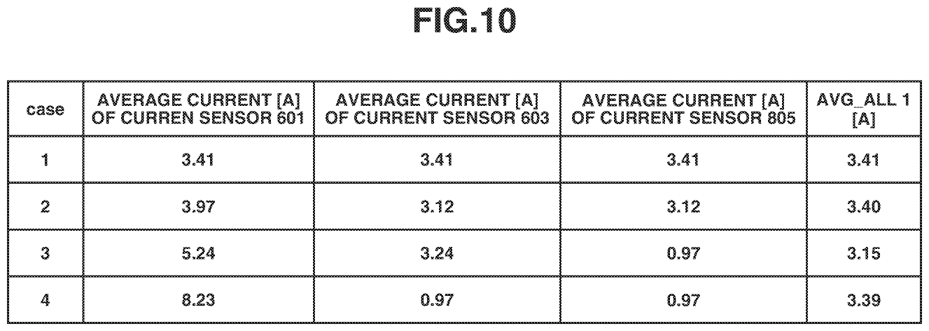

It is assumed that switching elements 201, 202, 203, and 204 in a power receiving circuit 121 and switching elements 202, 203, and 204 in power receiving circuits 122 and 181 are all normally operating. The simulations have been performed with changes only in the operations of the switching elements 201 in the power receiving circuits 122 and 181. Regarding the currents flowing in the current sensor 601, 603, and 805, FIG. 10 illustrates the results of simulations of average currents in the period during which the switching elements 201 in ON. FIG. 10 further illustrates the average values (AVG_ALL1) of the average currents flowing in these current sensors.

First, Case 1 indicates the results of the simulation in which the switching elements 201 in the power receiving circuits 121 and 181 are normally operating, and the values of the currents flowing in the three current sensors coincide with AVG_ALL1. Case 2 indicates the results of the simulation of a case in which the switching elements 201 in the power receiving circuit 121 and 181 have large ON resistances within a range of manufacturing errors. When the average values are compared with AVG_ALL1, “the average current of the current sensor 603 or 805/AVG_ALL1” is about 0.86. Case 3 indicates the results of the simulation of a case in which the switching element 201 in the power receiving circuit 121 has a large ON resistance in a range of manufacturing errors, and an abnormality has occurred in the switching element 201 in the power receiving circuit 181 and the ON resistance of the switching element 201 in the power receiving circuit 181 is abnormally large. The simulation result shows a case where the switching elements in the power receiving circuit 181 are larger in ON resistance than the switching elements in the power receiving circuit 121. When the average current values are compared with AVG_ALL1, “the average current of the current sensor 603/AVG_ALL1” is 1.02, and “the average current of the current sensor 805/AVG_ALL1” is 0.30. Case 4 indicates the results of the simulation of a case in which an abnormality has occurred in both the switching element 201 in the power receiving circuit 121 and the switching element 201 in the power receiving circuit 181 and both of the switching elements 201 have abnormally large ON resistances. When the average current values are compared with AVG_ALL1, “the average current of the current sensor 603 or 805/AVG_ALL1” is about 0.28.

As in the first exemplary embodiment, as the number of power receiving circuits increases, the average current of each current sensor÷AVG_ALL1 or AVG_ALL2 tends to be a smaller value, even in a case where the ON resistances of the switching elements are different within a range of normal manufacturing errors. For example, if the number of power receiving circuits is ten, the average current of each current sensor÷AVG_ALL1 or AVG_ALL2 is 0.67. In consideration of a system in practical use, the appropriate or reasonable number of power receiving circuits is about ten at the maximum. In addition, in consideration of the fact that some types of switching elements may have large manufacturing errors, the threshold for the average current of each current sensor÷AVG_ALL1 or AVG_ALL2 is appropriately 0.6.

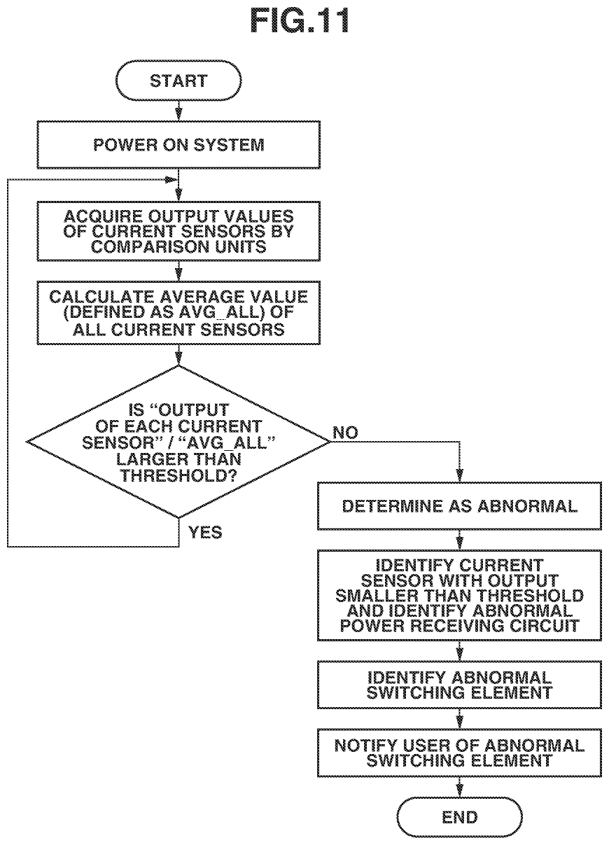

FIG. 11 is a flowchart illustrating a flow of operations of the wireless power transmission system including activation, detection of an abnormality, and notification to a user. First, the user or an external device powers on the wireless power transmission system, and the comparison units acquire output values proportional to the values of currents flowing in the current sensors implemented in the power receiving circuits. The average value (AVG_ALL) of the acquired values is calculated, the calculated result is compared with the output values of the current sensors, and the comparison results are transmitted to the abnormality detection unit. If all the output values of the comparison units are larger than the threshold, it is determined that the state is normal, and if any of the output values is smaller than the threshold, it is determined that the state is abnormal. The current sensor of which the output is less than the threshold is identified, and it is determined that an abnormality has occurred in the power receiving circuit to which the identified current sensor is connected. Further, it is determined that an abnormality has occurred in a switching element connected in series with the identified current sensor. At this time, since two switching elements are determined as candidates for the abnormal switching element, the abnormal switching element can be identified by monitoring the values of the voltages generated at both ends of the high resistor described above in the second exemplary embodiment. Finally, the user will be notified of the abnormal switching element.

In the first to third exemplary embodiments, the simulation results are presented in current waveform. The output values of the current sensors are analog voltage values, for example, that are proportional to the current values. Data processing can be performed on the output values of the current sensors by converting the voltage values into digital data by an analog-digital (AD) converter in the MCU.

In the first to third exemplary embodiments, the comparison units determine that an abnormality has occurred if the division value of the output values of the current sensors or the division value of the output value of each current sensor and the average value is larger than the threshold. Instead of the division value, it may be determined that an abnormality has occurred if the difference between the output values of the current sensors is larger than the threshold.

In the first to third exemplary embodiments, if a sampling period in which the output values of the current sensors are acquired is set to a period shorter than about 1/40 of the period of the CLK frequency, accurate output values can be acquired.

In the first to third exemplary embodiments, the results of simulations of a case in which the power receiving circuits are full-wave rectifier circuits are indicated. However, it is possible to perform abnormality detection in the same manner as described above in other circuit configurations in which the power receiving circuits are half-wave rectifier circuits or voltage doubler rectifier circuits.

### OTHER EMBODIMENTS

Various embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While exemplary embodiments have been described, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-071899, filed Apr. 25, 2023, which is hereby incorporated by reference herein in its entirety.

What is claimed is:

1. A power receiving device that wirelessly receives power from a power transmission device, the power receiving device comprising:
a power receiving antenna;
a plurality of power receiving circuits that each includes a switching element and is connected in parallel with each other;
a plurality of current detection sensors that is arranged in the plurality of power receiving circuits and is configured to output detection values;
one or more processors; and
one or more memories that store a computer-readable instruction for causing, when executed by the one or more processors, the power receiving device to:
compare the detection values output from the plurality of current detection sensors; and
determine whether an abnormality has occurred based on results of comparison.

2. The power receiving device according to claim 1,
wherein the plurality of current detection sensors is arranged at substantially identical positions in the plurality of power receiving circuits, and
wherein, if the detection values output from the plurality of current detection sensors are different from each other, the power receiving device determines that an abnormality has occurred.

3. The power receiving device according to claim 2,
wherein the plurality of current detection sensors is arranged at substantially the identical positions in the plurality of power receiving circuits, and
wherein the power receiving device calculates a division value using a smaller value of the detection values output from the plurality of current detection sensors as a numerator and a larger value of the detection values output from the plurality of current detection sensors as a denominator, and if the division value is smaller than a threshold, the power receiving device determines that an abnormality has occurred.

4. The power receiving device according to claim 3, wherein the threshold is 0.5.

5. The power receiving device according to claim 1, further comprising an average value calculation unit configured to calculate an average value of the detection values output from the plurality of current detection sensors arranged at substantially identical positions in the plurality of power receiving circuits,
Wherein, if the average value and at least one of the detection values output from the plurality of current detection sensors are different, the power receiving device determines that an abnormality has occurred.

6. The power receiving device according to claim 5, wherein the power receiving device calculates a division value using at least one of the detection values output from the plurality of current detection sensors as a numerator and the average value as a denominator, and if the division value is smaller than a threshold, the power receiving device determines that an abnormality has occurred.

7. The power receiving device according to claim 6, wherein the threshold is 0.6.

8. The power receiving device according to claim 1, wherein the plurality of current detection sensors is connected to output units of the plurality of power receiving circuits and a ground (GND).

9. The power receiving device according to claim 1, wherein the plurality of current detection sensors is each connected in series with the switching element.

10. A wireless power transmission system comprising:
a power transmission device configured to wirelessly transmit power; and
a power receiving device configured to wirelessly receive the power from the power transmission device, the power receiving device including:
a power receiving antenna;
a plurality of power receiving circuits that each includes a switching element and is connected in parallel with each other;
a plurality of current detection sensors that is arranged in the plurality of power receiving circuits and is configured to output detection values;
one or more processors; and
one or more memories that store a computer-readable instruction for causing, when executed by the one or more processors, the power receiving device to:
compare the detection values output from the plurality of current detection sensors; and
determine whether an abnormality has occurred based on results of comparison.
